(19) United States
(12) Patent Application Publication
(10) Pub. No.: US 2025/0248028 A1
(43) Pub. Date: Jul. 31, 2025

(54) BODY TIED TRANSISTOR DEVICE AND METHOD

(71) Applicant: Micron Technology, Inc., Boise, ID (US)

(72) Inventors: Si-Woo Lee, Saratoga, CA (US); Sameer Chhajed, Boise, ID (US); Durai Vishak Nirmal Ramaswamy, Boise, ID (US); Kamal M. Karda, Boise, ID (US); Haitao Liu, Boise, ID (US)

(21) Appl. No.: 19/036,978

(22) Filed: Jan. 24, 2025

Related U.S. Application Data
(60) Provisional application No. 63/625,564, filed on Jan. 26, 2024.

(51) Int. Cl. H10B 12/00

(52) U.S. Cl. CPC H10B 12/34; H10B 12/053

(57) ABSTRACT

Apparatus and methods are disclosed, including transistors, semiconductor devices and systems. Example semiconductor devices and methods include a dielectric isolation structure located at least partially beneath a semiconductor body and between the semiconductor body and a substrate. Example semiconductor devices and methods also include an electrical contact coupling the semiconductor body to the substrate. In one example, the electrical contact reduces or eliminates a floating body effect in the semiconductor body.

### PRIORITY APPLICATION

This application claims the benefit of priority to U.S. Provisional Application Ser. No. 63/625,564, filed Jan. 26, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates a cross section of a semiconductor device in accordance with some example embodiments.

FIG. 2B illustrates another cross section of the semiconductor device from FIG. 2A in accordance with some example embodiments.

FIG. 3A illustrates a diagram of a stage of manufacture of a semiconductor device in accordance with some example embodiments.

FIG. 3B illustrates a diagram of another stage of manufacture of a semiconductor device in accordance with some example embodiments.

FIG. 3C illustrates a diagram of another stage of manufacture of a semiconductor device in accordance with some example embodiments.

FIG. 3D illustrates a diagram of another stage of manufacture of a semiconductor device in accordance with some example embodiments.

FIG. 3E illustrates a diagram of another stage of manufacture of a semiconductor device in accordance with some example embodiments.

FIG. 3F illustrates a diagram of another stage of manufacture of a semiconductor device in accordance with some example embodiments.

FIG. 3G illustrates a diagram of another stage of manufacture of a semiconductor device in accordance with some example embodiments.

FIG. 3H illustrates a diagram of another stage of manufacture of a semiconductor device in accordance with some example embodiments.

FIG. 3I illustrates a diagram of another stage of manufacture of a semiconductor device in accordance with some example embodiments.

FIG. 3J illustrates a diagram of another stage of manufacture of a semiconductor device in accordance with some example embodiments.

FIG. 3K illustrates a diagram of another stage of manufacture of a semiconductor device in accordance with some example embodiments.

FIG. 4 illustrates a semiconductor device in accordance with some example embodiments.

FIG. 5 illustrates an example method flow diagram in accordance with other example embodiments.

FIG. 6 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

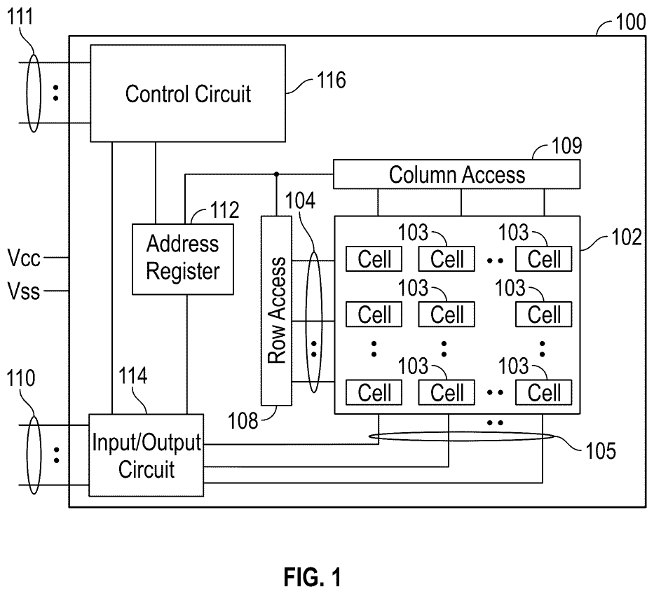

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

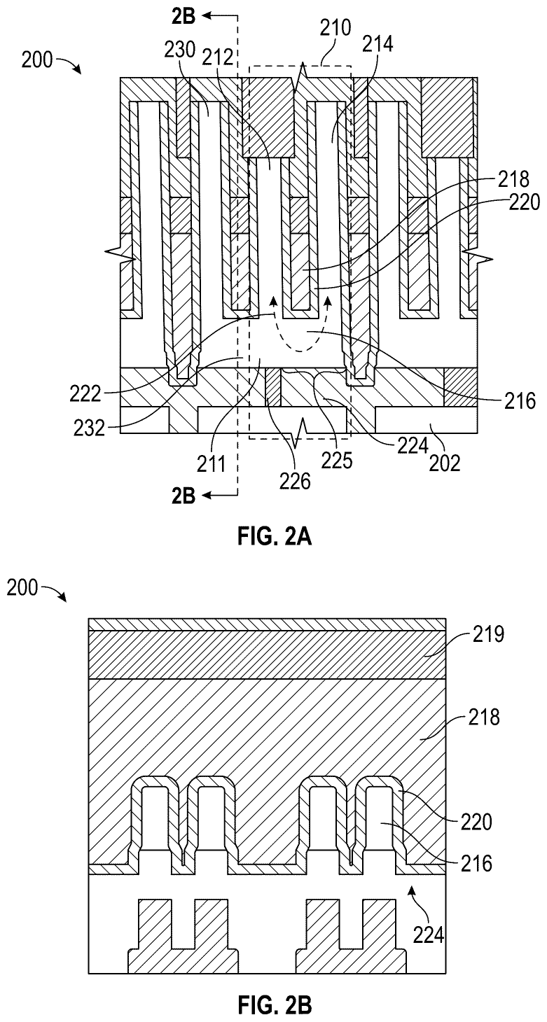

Memory cells 103 and other circuits 114, 116, etc. may include transistors and utilize methods as described in more detail in FIGS. 2A-4. In one example, memory arrays 102 include RAM storage, and peripheral circuits such as circuits 114, 116, 108, 109, etc. may include transistors as described in more detail in FIGS. 2A-4. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIG. 2A shows a semiconductor device 200. A transistor 210 is shown as part of the semiconductor device 200. The transistor 210 is located over a semiconductor substrate 202. In one example, the semiconductor substrate 202 includes silicon, although other semiconductor materials are also within the scope of the invention.

The transistor 210 includes a first source/drain region 212 extending upward from a semiconductor body 211. A second source/drain region 214 is also shown extending upward from the semiconductor body 211. A channel fin 216 is shown, coupled between the first source/drain region 212 and the second source/drain region 214. A gate 218 is shown separated from the channel fin 216 by a gate dielectric 220. In operation, a charge selectively applied to the gate 218 actuates conduction in the channel fin 216 and turns the transistor 210 on to open a signal path 222 between the first source/drain region 212 and the second source/drain region 214 through the channel fin 216.

A dielectric isolation structure 224 is further shown, located at least partially beneath the semiconductor body 211 and between the semiconductor body 211 and the substrate 202. A region 225 is shown illustrating the portion of the isolation structure 224 that is located beneath the semiconductor body 211. An electrical contact 226 is shown coupling the semiconductor body 211 to the substrate 202. In operation, it is desirable to provide a level of electrical coupling between the semiconductor body 211 and the substrate 202. The connection reduces or eliminates a floating body effect in the semiconductor body 211 and the channel fin 216. If the semiconductor body 211 and the channel fin 216 were completely electrically isolated from the substrate 202, a charge may become trapped in the semiconductor body 211 and the channel fin 216, reducing effectiveness in the signal path 222. Inclusion of the electrical contact 226 allows any floating body charge to dissipate and improves device performance.

The example semiconductor device 200 in FIGS. 2A and 2B includes a third source/drain region 230 extending upward from the semiconductor body 211 and a second channel fin 232 coupled between the third source/drain region 230 and the first source/drain region 212. In this configuration, two transistors are formed that share a common first source/drain region 212. This configuration provides higher device areal density by sharing components.

FIG. 2B shows a cross section of the semiconductor device from FIG. 2A. FIG. 2B illustrates how the gate 218 is configured to be adjacent to the channel fin 216 on three sides, with the isolation structure 224 underneath. This configuration provides an efficient control of the channel fin 216 without electrical interference from adjacent structures. In the example shown, an additional conductor layer 219 is included over the gate 218. In one example, the gate 218 includes a metal or conductive alloy. Example materials for gate 218 include, but are not limited to, molybdenum, tungsten, ruthenium titanium nitride, and/or alloys that include these metals. In one example, the additional conductor layer 219 includes a material that modifies a work function of the gate 218 material. One example material for the conductor layer 219 includes an N+ polysilicon layer, although the invention is not so limited.

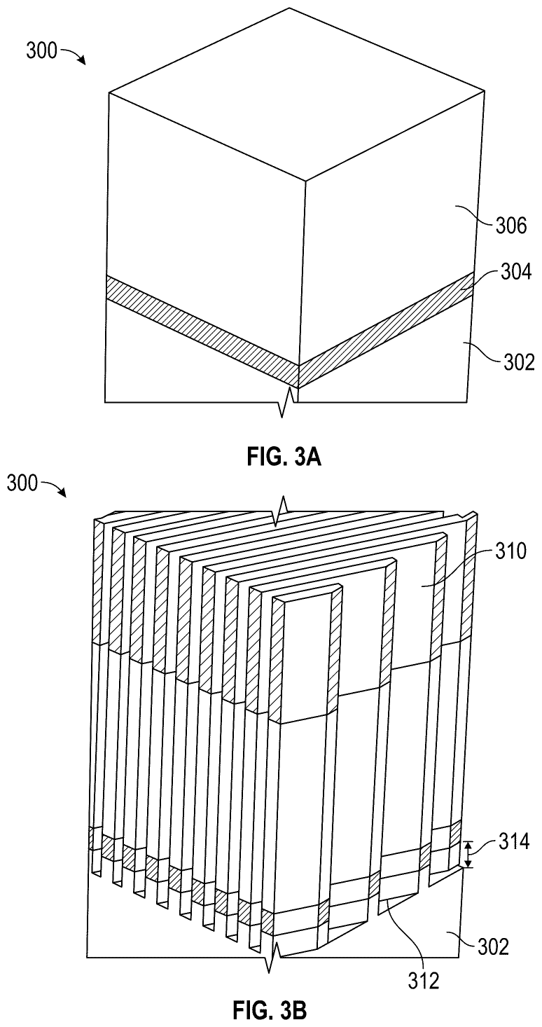

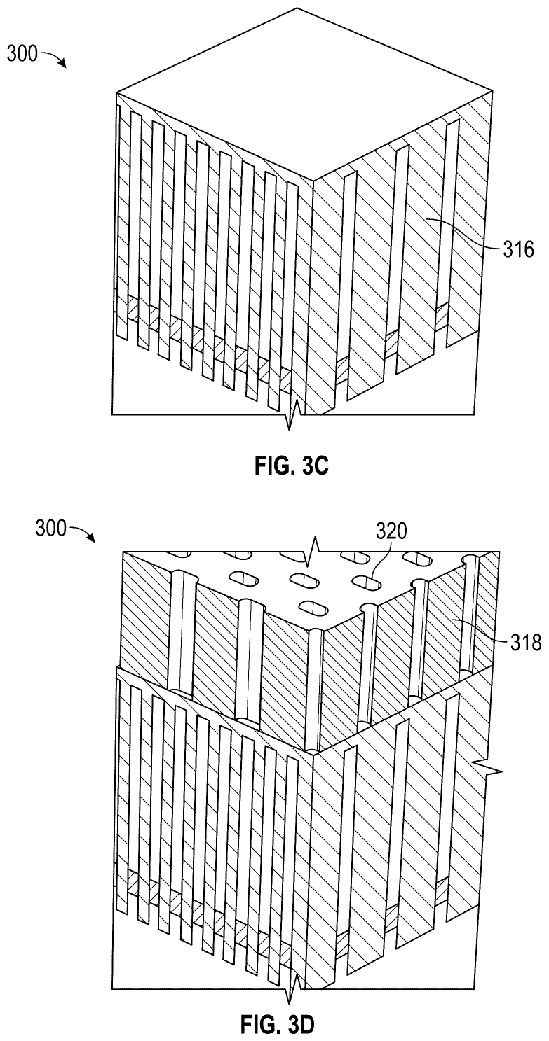

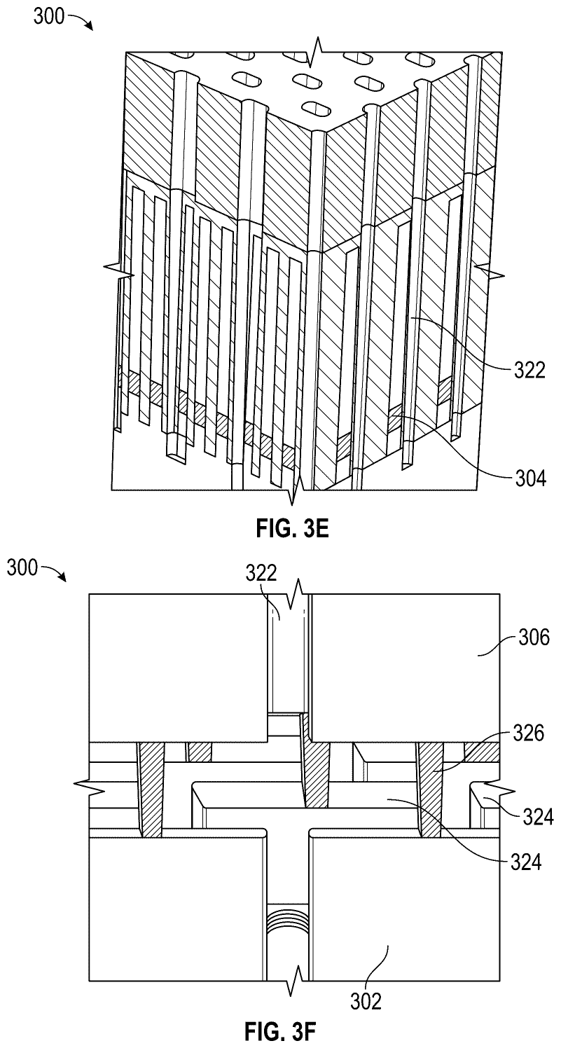

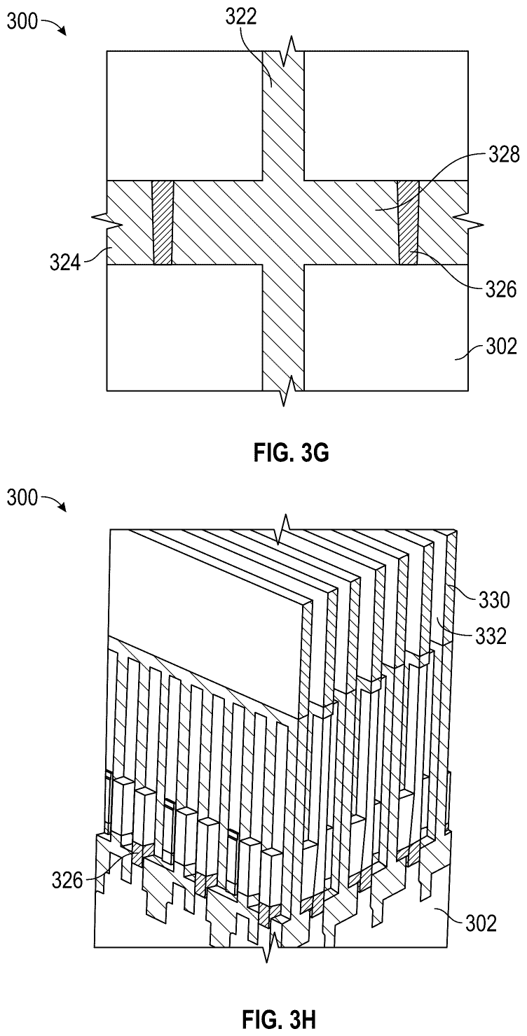

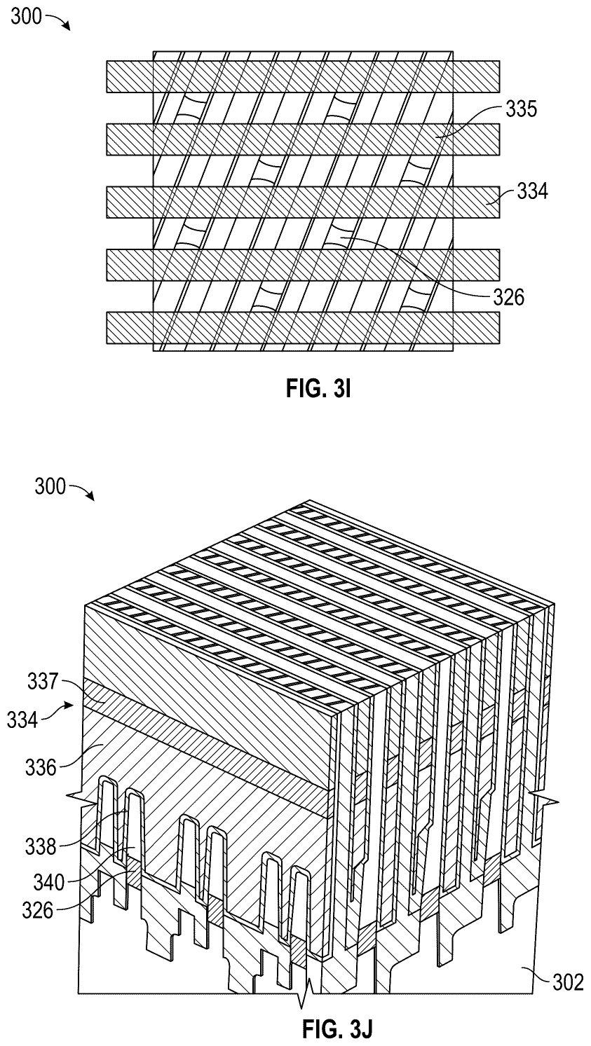

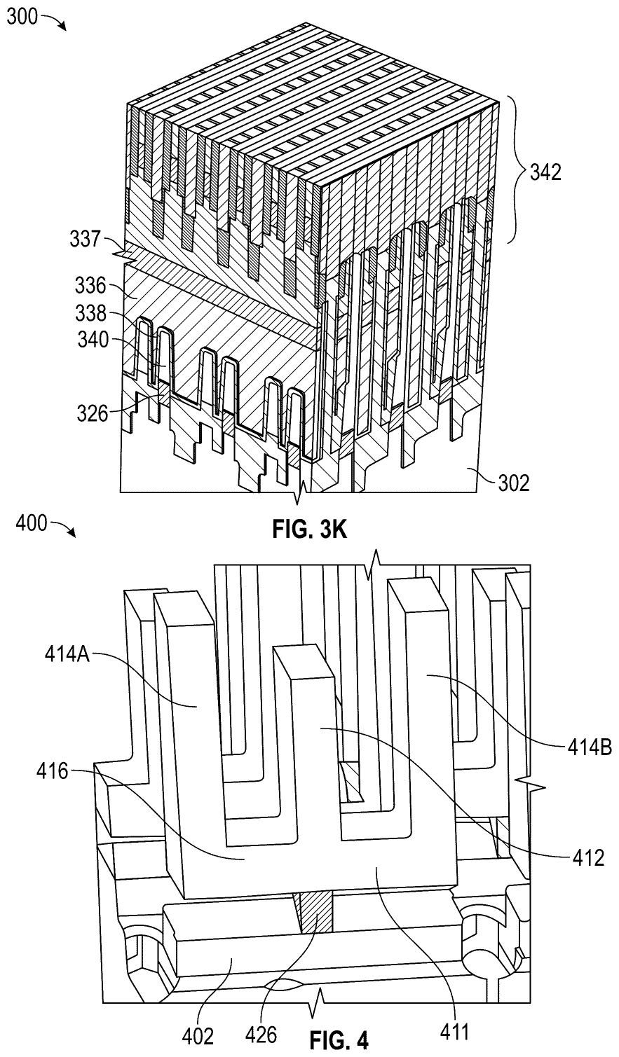

FIGS. 3A-3K shows selected stages of manufacture in one example method of forming a semiconductor device 300. FIG. 3A shows a substrate 302 such as a silicon substrate. Other semiconductors are also within the scope of the invention. A conducting layer 304 is included, with a second semiconductor layer located over the conducting layer 304. In one example, the conducting layer 304 includes silicon germanium. In one example, the silicon germanium is in a stoichiometric ratio of SiₓGe₍₁₋ₓ₎. As discussed in more detail below, varying a stoichiometric ratio of SiₓGe₍₁₋ₓ₎ provides a processing advantage in the formation of the electrical contact 226 as shown in FIGS. 2A-2B.

In one example, the substrate 302 includes single crystalline silicon, and the conducting layer 304 and a second semiconductor layer 306 are epitaxially formed on the substrate 302. Epitaxial formation provides a crystalline structure with semiconducting properties that improve operation of transistors and other semiconductor devices formed from the conducting layer 304 and the second semiconductor layer 306.

FIG. 3B shows a mask layer 310 patterned over the second semiconductor layer 306. A number of trenches 312 are patterned and formed in the second semiconductor layer 306. In one example, the number of trenches 312 define a number of isolation structures that electrically separate semiconductor devices. A depth 314 of the trenches 312 is shown in FIG. 3B. Devices formed using methods described in the present disclosure enable the depth 314 to be shallower than other configurations. One configuration feature that contributes to enabling a shallow depth 314 includes the region 225 of the isolation structure 224 that is located beneath the semiconductor body 211. The increased isolation of the semiconductor body 211 reduces a need for deeper trenches 312.

FIG. 3C shows a dielectric 316 that has been filled into the trenches 312. In FIG. 3D, a mask 318 is formed with openings 320 in the mask 318. Using the openings 320, a deep etch is made into the dielectric 316 to a level that at least exposes the conducting layer 304. The deep etch openings 322 are shown in FIG. 3E.

With the conducting layer 304 exposed through the deep etch openings 322, a portion of the conducting layer 304 is exhumed through the deep etch openings 322. In one example, a wet etch chemistry that is selective to the material in the conducting layer 304 is used. As illustrated in FIG. 3F, only a portion of the conducting layer 304 is exhumed, leaving an electrical contact 326 coupled between the semiconductor layer 306 and the substrate 302. Portions of the conducting layer 304 are removed from regions 324 on either side of the remaining electrical contact 326.

As discussed above, one example conducting layer 304 includes silicon germanium. In one example, the silicon germanium is in a stoichiometric ratio of SiₓGe₍₁₋ₓ₎. By varying the “x” in the stoichiometric ratio, the conducting layer 304 is tuned to a high selectivity in the exhuming etch chemistry. In one example, an “x” in the ratio of SiₓGe₍₁₋ₓ₎ is between 0.1 and 0.8. In one example, an “x” in the ratio of SiₓGe₍₁₋ₓ₎ is between 0.2 and 0.6. In one example, an “x” in the ratio of SiₓGe₍₁₋ₓ₎ is between 0.3 and 0.5. By using a selective etch, only the conducting layer 304 is affected, and the remaining silicon and dielectric structures remain after exhuming the portion of the conducting layer 304.

In FIG. 3G, the deep etch openings 322 and the regions 324 on either side of the remaining electrical contact 326 are filled with a dielectric material 328. In one example, the dielectric material 328 is the same as the dielectric 316, although the invention is not so limited. Different dielectric material may also be used. One example of a dielectric material includes silicon oxide, although the invention is not so limited. Other dielectric materials may also be used.

FIG. 3H shows formation of a second mask 330 and subsequent

formation of wordline trenches 332. FIG. 3I shows a top view of the semiconductor device 300 with wordlines 334 formed in the wordline trenches 332. The wordlines 334 are formed over channel fins 335, similar to channel fins 216 from FIGS. 2A and 2B. The electrical contact 326 is also shown in FIG. 3I.

FIG. 3J shows the semiconductor device 300 with wordlines similar to wordlines 334 formed from a first conductor layer 336 and a second conductor layer 337. The first conductor layer 336 is shown formed over channel fins 340. The first conductor layer 336 is separated from the channel fins 340 by a gate dielectric 338. This configuration forms the main structure of transistor gates that are part of the first conductor layer 336 in wordlines 334. In the example shown, the wordlines 334 include two conductors 336, 337 although the invention is not so limited. A single conductor used to form wordlines 334, or more than two conductors used to form wordlines 334 are also within the scope of the invention. As discussed in examples above, an additional conductor layer 337 may be included to modify a work function of a transistor gate.

FIG. 3K shows a further stage of processing of the example semiconductor device 300. In FIG. 3K, an interconnection layer 342 is shown. Examples of structures in the interconnection layer 342 include, but are not limited to, digit line connections, cell contact connections, etc. Combinations of dielectric layers and conductor layers are used to form the interconnection layer 342 of FIG. 3K.

FIG. 4 shows a semiconductor device 400 with a number of components removed to illustrate a general geometry of the semiconductor device 400. In the example of FIG. 4, the semiconductor device 400 is similar to the semiconductor device 300 shown in FIGS. 3A-3K.

In FIG. 4, a first source/drain region 412 is shown extending upward from a semiconductor body 411. A second source/drain region 414A is also shown extending upward from the semiconductor body 411. A channel fin 416 is shown as part of the semiconductor body 411, coupled between the first source/drain region 412 and the second source/drain region 414A. An electrical contact 426, similar to electrical contact 326, is shown coupling the semiconductor body 411 to a substrate 402. FIG. 4 further shows a third source/drain region 414B extending upward from the semiconductor body 411. In this configuration, two transistors are formed that share a common first source/drain region 412. This configuration provides higher device areal density by sharing components.

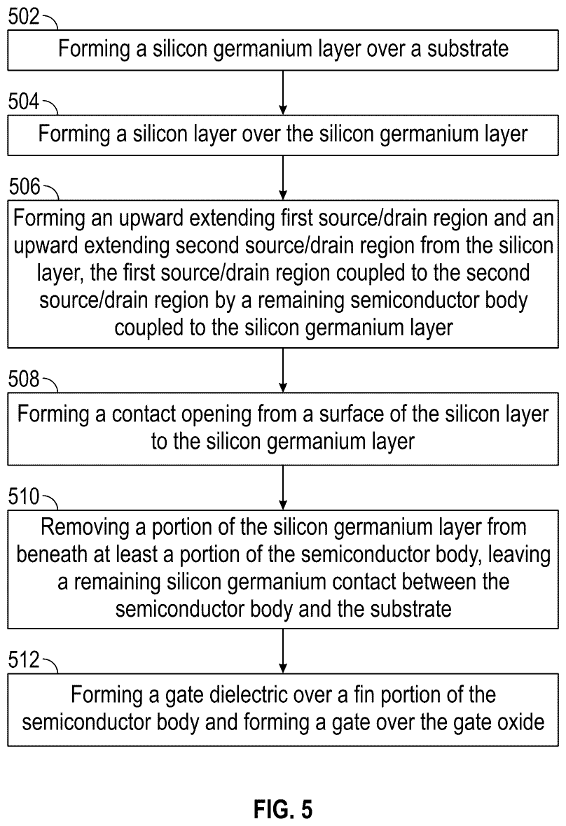

FIG. 5 shows a flow diagram of one example method of manufacture. In operation 502, a silicon germanium layer is formed over a substrate. In operation 504, a silicon layer is formed over the silicon germanium layer. In operation 506, an upward extending first source/drain region and an upward extending second source/drain region are formed from the silicon layer, the first source/drain region coupled to the second source/drain region by a remaining semiconductor body coupled to the silicon germanium layer. In operation 508, an opening is formed from a surface of the silicon layer to the silicon germanium layer. In operation 510, a portion of the silicon germanium layer is removed from beneath at least a portion of the semiconductor body, leaving a remaining silicon germanium contact between the semiconductor body and the substrate. In operation 512, a gate dielectric is formed over a fin portion of the semiconductor body and forming a gate over the gate oxide.

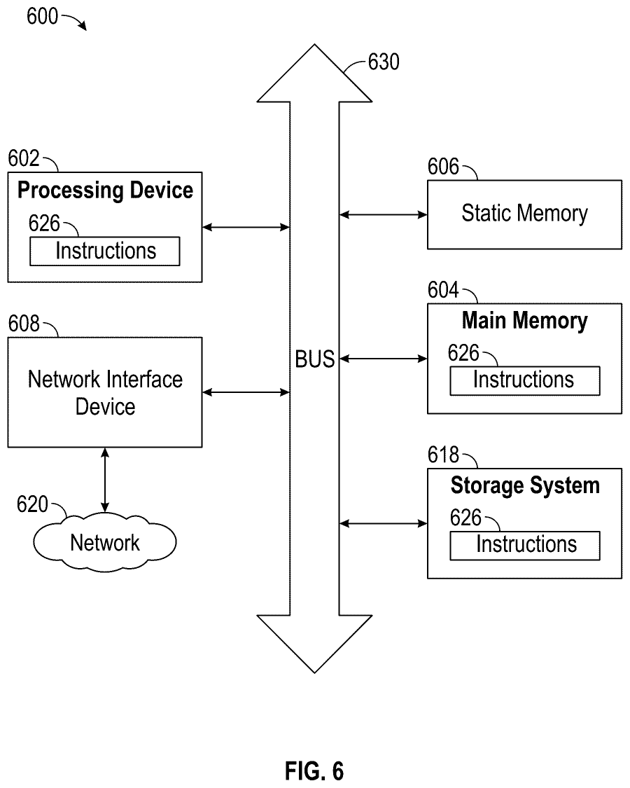

FIG. 6 illustrates a block diagram of an example machine (e.g., a host system) 600 which may include one or more transistors, memory devices and/or memory systems as described above. As discussed above, machine 600 may benefit from enhanced memory performance from use of one or more of the described transistor structures and/or memory systems, facilitating improved performance of machine 600 (as for many such machines or systems, efficient reading and writing of memory can facilitate improved performance of a processor or other components that machine, as described further below.

In alternative embodiments, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 600 may include a processing device 602 (e.g., a hardware processor, a central processing unit (CPU), a graphics processing unit (GPU), a hardware processor core, or any combination thereof, etc.), a main memory 604 (e.g., read-only memory (ROM), dynamic random-access memory (DRAM) such as synchronous DRAM (SDRAM) or Rambus DRAM (RDRAM), etc.), a static memory 606 (e.g., static random-access memory (SRAM), etc.), and a storage system 618, some or all of which may communicate with each other via a communication interface (e.g., a bus) 630. In one example, the main memory 604 includes one or more memory devices as described in examples above.

The processing device 602 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 can be configured to execute instructions 626 for performing the operations and steps discussed herein. The computer system 600 can further include a network interface device 608 to communicate over a network 620.

The storage system 618 can include a machine-readable storage medium (also known as a computer-readable medium) on which is stored one or more sets of instructions 626 or software embodying any one or more of the methodologies or functions described herein. The instructions 626 can also reside, completely or at least partially, within the main memory 604 or within the processing device 602 during execution thereof by the computer system 600, the main memory 604 and the processing device 602 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 600 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 600 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 626 (e.g., software, programs, an operating system (OS), etc.) or other data are stored on the storage system 618 can be accessed by the main memory 604 for use by the processing device 602. The main memory 604 (e.g., DRAM) is typically fast, but volatile, and thus a different type of storage than the storage system 618 (e.g., an SSD), which is suitable for long-term storage, including while in an “off” condition. The instructions 626 or data in use by a user or the machine 600 are typically loaded in the main memory 604 for use by the processing device 602. When the main memory 604 is full, virtual space from the storage system 618 can be allocated to supplement the main memory 604; however, because the storage system 618 device is typically slower than the main memory 604, and write speeds are typically at least twice as slow as read speeds, use of virtual memory can greatly reduce user experience due to storage system latency (in contrast to the main memory 604, e.g., DRAM). Further, use of the storage system 618 for virtual memory can greatly reduce the usable lifespan of the storage system 618.

The instructions 626 may further be transmitted or received over a network 620 using a transmission medium via the network interface device 608 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 608 may include one or more physical jacks (e.g., Ethernet, coaxial, or phone jacks) or one or more antennas to connect to the network 620. In an example, the network interface device 608 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 600, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Example 1. A semiconductor device, comprising: a first source/drain region extending upward from a semiconductor body; a second source/drain region extending upward from the semiconductor body; wherein the semiconductor body includes a channel fin coupled between the first source/drain region and the second source/drain region; a gate separated from the channel fin by a gate dielectric; a dielectric isolation structure located at least partially beneath the semiconductor body and between the semiconductor body and a substrate; and an electrical contact coupling the semiconductor body to the substrate.

Example 2. The semiconductor device of example 1, wherein the electrical contact is centered beneath the semiconductor body.

Example 3. The semiconductor device of example 1, wherein the electrical contact includes silicon and germanium.

Example 4. The semiconductor device of example 3, wherein the electrical contact includes silicon and germanium in a ratio of SiₓGe₍₁₋ₓ₎ where x is between 0.1 and 0.8.

Example 5. The semiconductor device of example 1, further including a third source/drain region extending upward from the semiconductor body; and wherein the semiconductor body includes a second channel fin coupled between the third source/drain region and the first source/drain region.

Example 6. The semiconductor device of example 1, wherein the gate includes more than one layer of different conductors.

Example 7. The semiconductor device of example 1, wherein the electrical contact includes a thickness of 10-20 nm.

Example 8. A semiconductor device, comprising: a first source/drain region extending upward from a semiconductor body; a second source/drain region extending upward from the semiconductor body; wherein the semiconductor body includes a channel fin coupled between the first source/drain region and the second source/drain region; a gate separated from the channel fin by a gate dielectric; a dielectric isolation structure located at least partially beneath the semiconductor body and between the semiconductor body and a substrate; an electrical contact coupling the semiconductor body to the substrate; and a dielectric isolation trench adjacent to the semiconductor body, wherein the dielectric isolation trench extends into the substrate.

Example 9. The semiconductor device of example 8, wherein the dielectric isolation trench extends into the substrate deeper than a bottom of the electrical contact.

Example 10. The semiconductor device of example 8, wherein the dielectric isolation trench extends into the substrate to a depth less than 250 nm.

Example 11. The semiconductor device of example 10, wherein the dielectric isolation trench extends into the substrate to a depth of 150 nm or less.

Example 12. The semiconductor device of example 8, wherein the gate wraps around the channel fin on three sides, and wherein a fourth side of the channel fin abuts the dielectric isolation structure.

Example 13. The semiconductor device of example 8, further including a third source/drain region extending upward from the semiconductor body; and wherein the semiconductor body includes a second channel fin coupled between the third source/drain region and the second source/drain region.

Example 14. The semiconductor device of example 13, wherein the gate is included in a wordline.

Example 15. The semiconductor device of example 14, wherein the first and third source/drain regions are coupled to cell contacts and the second source/drain region is coupled to a digit line.

Example 16. A method of forming a semiconductor device, comprising: forming a silicon germanium layer over a substrate; forming a silicon layer over the silicon germanium layer; forming an upward extending first source/drain region and an upward extending second source/drain region from the silicon layer, the first source/drain region coupled to the second source/drain region by a remaining semiconductor body coupled to the silicon germanium layer; forming a contact opening from a surface of the silicon layer to the silicon germanium layer; removing a portion of the silicon germanium layer from beneath at least a portion of the semiconductor body, leaving a remaining silicon germanium contact between the semiconductor body and the substrate; and forming a gate dielectric over a fin portion of the semiconductor body and forming a gate over the gate dielectric.

Example 17. The method of example 16, wherein forming a silicon layer over the silicon germanium layer includes epitaxially growing the silicon layer over the silicon germanium layer.

Example 18. The method of example 16, wherein removing a portion of the silicon germanium layer includes etching.

Example 19. The method of example 16, wherein forming a silicon germanium layer over a substrate includes forming a layer including silicon and germanium in a ratio of SiₓGe₍₁₋ₓ₎ where x is in a range between 0.1 and 0.8.

Example 20. The method of example 19, wherein removing a portion of the silicon germanium layer from beneath at least a portion of the semiconductor body includes selecting the ratio with a highest etch selectivity of the silicon germanium layer in the range.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor device, comprising:
a first source/drain region extending upward from a semiconductor body;
a second source/drain region extending upward from the semiconductor body;
wherein the semiconductor body includes a channel fin coupled between the first source/drain region and the second source/drain region;
a gate separated from the channel fin by a gate dielectric;
a dielectric isolation structure located at least partially beneath the semiconductor body and between the semiconductor body and a substrate; and
an electrical contact coupling the semiconductor body to the substrate.

2. The semiconductor device of claim 1, wherein the electrical contact is centered beneath the semiconductor body.

3. The semiconductor device of claim 1, wherein the electrical contact includes silicon and germanium.

4. The semiconductor device of claim 3, wherein the electrical contact includes silicon and germanium in a ratio of SiₓGe₍₁₋ₓ₎ where x is between 0.1 and 0.8.

5. The semiconductor device of claim 1, further including a third source/drain region extending upward from the semiconductor body; and
wherein the semiconductor body includes a second channel fin coupled between the third source/drain region and the first source/drain region.

6. The semiconductor device of claim 1, wherein the gate includes more than one layer of different conductors.

7. The semiconductor device of claim 1, wherein the electrical contact includes a thickness of 10-20 nm.

8. A semiconductor device, comprising:
a first source/drain region extending upward from a semiconductor body;
a second source/drain region extending upward from the semiconductor body;
wherein the semiconductor body includes a channel fin coupled between the first source/drain region and the second source/drain region;
a gate separated from the channel fin by a gate dielectric;
a dielectric isolation structure located at least partially beneath the semiconductor body and between the semiconductor body and a substrate;
an electrical contact coupling the semiconductor body to the substrate; and
a dielectric isolation trench adjacent to the semiconductor body, wherein the dielectric isolation trench extends into the substrate.

9. The semiconductor device of claim 8, wherein the dielectric isolation trench extends into the substrate deeper than a bottom of the electrical contact.

10. The semiconductor device of claim 8, wherein the dielectric isolation trench extends into the substrate to a depth less than 250 nm.

11. The semiconductor device of claim 10, wherein the dielectric isolation trench extends into the substrate to a depth of 150 nm or less.

12. The semiconductor device of claim 8, wherein the gate wraps around the channel fin on three sides, and wherein a fourth side of the channel fin abuts the dielectric isolation structure.

13. The semiconductor device of claim 8, further including a third source/drain region extending upward from the semiconductor body; and
wherein the semiconductor body includes a second channel fin coupled between the third source/drain region and the second source/drain region.

14. The semiconductor device of claim 13, wherein the gate is included in a wordline.

15. The semiconductor device of claim 14, wherein the first and third source/drain regions are coupled to cell contacts and the second source/drain region is coupled to a digit line.

16. A method of forming a semiconductor device, comprising:
forming a silicon germanium layer over a substrate;
forming a silicon layer over the silicon germanium layer;
forming an upward extending first source/drain region and an upward extending second source/drain region from the silicon layer, the first source/drain region coupled to the second source/drain region by a remaining semiconductor body coupled to the silicon germanium layer;
forming a contact opening from a surface of the silicon layer to the silicon germanium layer;
removing a portion of the silicon germanium layer from beneath at least a portion of the semiconductor body, leaving a remaining silicon germanium contact between the semiconductor body and the substrate; and
forming a gate dielectric over a fin portion of the semiconductor body and forming a gate over the gate dielectric.

17. The method of claim 16, wherein forming a silicon layer over the silicon germanium layer includes epitaxially growing the silicon layer over the silicon germanium layer.

18. The method of claim 16, wherein removing a portion of the silicon germanium layer includes etching.

19. The method of claim 16, wherein forming a silicon germanium layer over a substrate includes forming a layer including silicon and germanium in a ratio of SiₓGe₍₁₋ₓ₎ where x is in a range between 0.1 and 0.8.

20. The method of claim 19, wherein removing a portion of the silicon germanium layer from beneath at least a portion of the semiconductor body includes selecting the ratio with a highest etch selectivity of the silicon germanium layer in the range.
